(19) United States
(12) Patent Application Publication
(10) Pub. No.: US 2010/0309035 A1
(43) Pub. Date: Dec. 9, 2010

(54) METHOD AND APPARATUS TO IMPROVE REFERENCE VOLTAGE ACCURACY

(76) Inventors: QINGHUA YUE, Shanghai (CN); Lijie Zhao, Shanghai (CN); Song Gao, Tempe, AZ (US)

Correspondence Address: HAYNES AND BOONE, LLP;IP Section, 2323 Victory Avenue, Suite 700, Dallas, TX, 75219, US

(21) Appl. No.: 12/481,423

(22) Filed: Jun. 9, 2009

(51) Int. Cl. H03M 1/02

(52) U.S. Cl. 341/141

(57) ABSTRACT

A method and apparatus for converting an analog input voltage signal to a discrete signal, the method including generating at least one reference voltage and at least one secondary voltage. The method further including selecting at least one voltage between the at least one reference voltage and the at least one secondary voltage and generating at least one intermediate voltage based on the at least one voltage and at least one digital code. The at least one intermediate voltage and the analog input voltage further being used to generate at least one comparison signal and the discrete signal being generated based on the at least one comparison signal and the at least one digital code.

### TECHNICAL FIELD

This invention relates generally to the field of electronic circuits and, more particularly, to methods and systems for improving reference voltage accuracy in capacitor arrays that may be used in various electronic circuits.

### DISCUSSION OF RELATED ART

Technological advances in digital transmission networks, digital storage media, Very Large Scale Integration devices, and digital signal processing have resulted in an increased demand in the conversion of signals from an analog domain to a digital domain and vice-versa.

Over the years, various analog-to-digital converters (ADC) and conversion techniques have been developed for converting electrical signals from an analog domain to a digital domain. Typically, the process of analog-to-digital conversion includes sampling an analog signal and comparing the sampled analog signal to a threshold value. A digital word can be recorded depending upon the result of the comparison.

Currently, Complementary Metallic Oxide Semiconductor (CMOS) integrated circuit technology is becoming more commonplace. CMOS technology is relatively inexpensive and yet versatile in allowing designers to include digital logic circuitry and analog circuitry in the same integrated circuit, which is applicable to ADC's.

As the requirements for precision have continued to increase with respect to ADC's, the use of resistor networks for sampling has been substantially reduced due to the difficulty in producing accurate resistors using CMOS technology. Instead, techniques which utilizes capacitor networks instead of resistor networks have become the most commonly used methodology in CMOS ADC technology.

Capacitor arrays or ladders are commonly employed in analog-to-digital converters, digital-to-analog converters, switched-capacitor filters, or other such circuits. However, in capacitor related circuits, factors such as current surges, parasitic conductor effect, capacitance mismatch, or other such effects can affect the accuracy of reference source voltages that can be included which can in turn degrade performance.

Therefore, there is a need for more efficient methods that can improve the reference voltage accuracy in capacitor related circuits.

### SUMMARY

Consistent with some embodiments of the present invention, a method for converting an analog input voltage signal to a discrete signal includes generating at least one reference voltage and at least one secondary voltage. The method further includes selecting at least one voltage between the at least one reference voltage and the at least one secondary voltage and generating at least one intermediate voltage based on the at least one voltage and at least one digital code. The at least one intermediate voltage and the analog input voltage further being used to generate at least one comparison signal and the discrete signal being generated based on the at least one comparison signal and the at least one digital code.

In another embodiment, an analog to digital converter (ADC) for converting an analog input voltage to a discrete signal includes a reference generator unit (RGU) for generating at least one reference voltage, a secondary voltage source (SVS) for generating at least one secondary voltage and a multiplexer coupled to receive the at least one secondary voltage and the at least one reference voltage. The multiplexer further configured to select between the at least one reference voltage and the at least one secondary voltage based on a control signal. The ADC further includes a digital to analog converter (DAC) coupled to receive the analog input voltage, at least one voltage from the multiplexer, and at least one digital code. The DAC further generates at least one intermediate voltage based on the at least one digital code. The ADC also includes a comparator coupled to receive the analog input voltage and the at least one intermediate voltage, the comparator further configured to generate at least one comparison signal, and a control logic unit (CLU) coupled to receive a clock signal and the comparison signal, the CLU configured to generate the control signal and the at least one digital code, the CLU further generating the discrete signal.

Additional features and advantages of the invention will be set forth in part in the description which follows, and in part will be obvious from the description, or may be learned by practice of the invention. The features and advantages of the invention will be realized and attained by means of the elements and combinations particularly pointed out in the appended claims.

### BRIEF DESCRIPTION OF THE DRAWINGS

FIG. 1 illustrates a block diagram of a signal processing system consistent with some embodiments of the present invention.

FIG. 2 illustrates a block diagram of an analog-to-digital converter (ADC) consistent with some embodiments of the present invention.

FIG. 3 illustrates a schematic of a digital-to-analog converter (DAC) consistent with some embodiments of the present invention.

FIG. 4 illustrates another block diagram of an analog-to-digital converter (ADC) consistent with some embodiments of the present invention.

FIGS. 5a and 5b are graphs illustrating performance of an ADC consistent with some embodiments of the present invention.

In the figures, elements having the same designation have the same or similar functions.

The accompanying drawings, which are incorporated in and constitute a part of this specification, illustrate embodiments of the invention and, together with the description, serve to explain the principles of the invention.

### DETAILED DESCRIPTION

Reference will now be made in detail to embodiments of the present invention, examples of which are illustrated in the accompanying drawings. Wherever possible, the same reference numbers are used throughout the drawings to refer to the same or like parts.

In the following description and claims, the terms “coupled” and “connected,” along with their derivatives, may be used. It should be understood that these terms are not intended as synonyms for each other. Rather, in particular embodiments, “connected” and/or “coupled” may be used to indicate that two or more elements are in direct physical or electronic contact with each other. However, “coupled” may also mean that two or more elements are not in direct contact with each other, but yet still cooperate, communicate, and/or interact with each other.

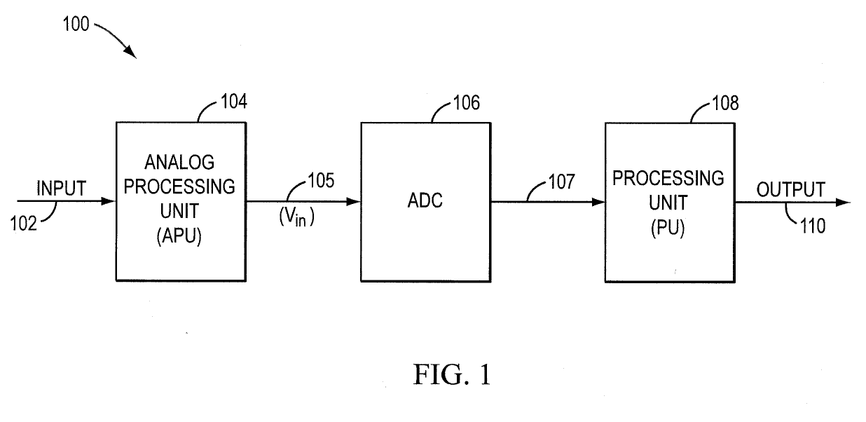

FIG. 1 illustrates a block diagram of an exemplary signal processing system 100 consistent with some embodiments of the present system. In practice, exemplary system 100 can be included in any electronic system that can include the conversion and/or processing of signals in the analog and digital domains. For example, system 100 can be a part of a digital recorder, mobile phone, a MP3 player, or other such electronic systems.

It should be understood that various functional units discussed in the following description and claims can, in practice, individually or in any combinations, be implemented in hardware, in software executed on one or more hardware components (such as one or more processors, one or more application specific integrated circuits (ASIC's) or other such components), or in any combination thereof.

As shown in FIG. 1, system 100 can include an analog processing unit (APU) 104 that can be coupled to receive an input signal 102 from a source. Input signal 102 can include any audio, video, or data signal. In some embodiments, signal 102 can be received from an antenna (not shown). APU 104 can be configured to generate a processed signal 105 (having a voltage Vᵢₙ) by performing functions such as filtering, amplification (or attenuation), frequency conversion, or other such functions on input signal 102. In some embodiments, signal 102 and signal 105 may be similar if not identical to one another.

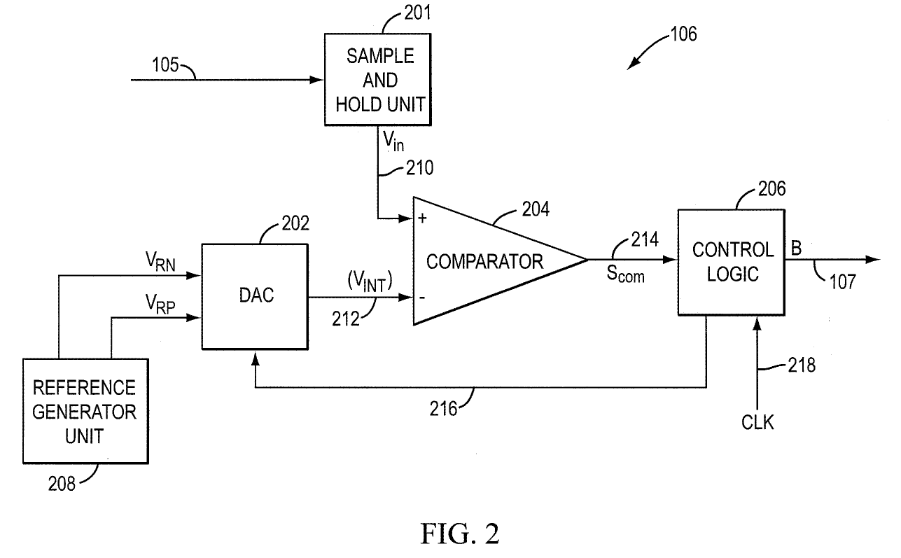

System 100 can further include an analog to digital converter (ADC) 106 that can be coupled to receive processed signal 105 (from APU 104) and can be configured to convert processed input signal 105 into a discrete signal 107 that can include one or more binary bits. The operation of an ADC such as exemplary ADC 106 will be discussed below with respect to FIG. 2.

As shown in FIG. 1, system 100 can also include a processing unit (PU) 108 that can be coupled to receive discrete signal 107 from ADC 106 and can be configured to process signal 107 to generate data that can be further provided as an input to various audio, video or data applications.

FIG. 2 is a block diagram illustrating the operation of ADC 106 consistent with some embodiments of the present invention. As shown in FIG. 2, ADC 106 can include a comparator 204 that can be coupled to receive (via an input terminal 210) an input voltage Vᵢₙ associated with input signal 105. Comparator 204 can be further coupled to receive (via an input terminal 212) an intermediate voltage V_{INT}) and can be configured to compare intermediate voltage V_{INT} with input voltage Vᵢₙ. Comparator 204 can generate a comparison signal S_{com} via output terminal 214 that can include information that can indicate a result of the comparison between V_{INT} and Vᵢₙ. In some embodiments, for example, comparison signal S_{com} can be a binary signal that can include a logical value ‘1’ if Vᵢₙ is greater than V_{INT}, or a logical value of ‘0’ if Vᵢₙ is less than or equal to V_{INT}.

In some embodiments, comparator 204 can be coupled to a sample and hold unit (SHU) 201. SHU 201 can be coupled to receive input signal 105 and can be configured to sample signal 105 to generate a plurality of voltage samples (Vᵢₙ) associated with signal 105. In some embodiments, comparator 204 can compare inputs via terminals 210 and 212 on a sample by sample basis.

As shown in FIG. 2, ADC 106 can further include a control logic unit (CLU) 206 that can be coupled to receive signal S_{com} and a clock signal (CLK) 218, and can be configured to generate discrete signal 107 that can correspond with each input voltage sample Vᵢₙ. In some embodiments, each input voltage sample can be represented as a N bit digital code in discrete signal 107. In some embodiments, CLU 206 can be configured to generate discrete signal 107 by implementing a successive approximation scheme. In the successive approximation scheme, CLU 206 can be configured to determine one or more bits of discrete signal 107 corresponding with a given input voltage sample by performing one or more iterations. During each iteration, CLU 206 can generate an intermediate digital code 216 that can correspond with one or more bits of discrete signal 107. Intermediate digital code 216 can further correspond to a value (in volts) of the given input voltage sample. In some embodiments, CLK 218 can control a duration of each iteration performed by CLU 206. In some embodiments, CLK 218 can operate with different durations in different iterations.

As shown in FIG. 2, ADC 106 can further include a digital-to-analog converter (DAC) 202. DAC 202 can be coupled to receive a positive reference voltage V_{RP}, a negative reference voltage V_{RN}, and intermediate digital code 216. DAC 202 can be further configured to generate intermediate voltage V_{INT}. As shown in FIG. 2, in some embodiments, positive and negative voltages (V_{RP} and V_{RN}, respectively) can be generated by a reference generator unit (RGU) 208. For convenience, FIG. 2 depicts RGU 208 as generating two reference voltages V_{RN} and V_{RP}. However, it should be understood that in practice, RGU 208 can generate any number of reference voltages. Therefore, the present disclosure is not limited in the number of reference voltages that can be included in an ADC consistent with the present invention. In some embodiments, DAC 202 can also be coupled to receive input voltage Vᵢₙ.

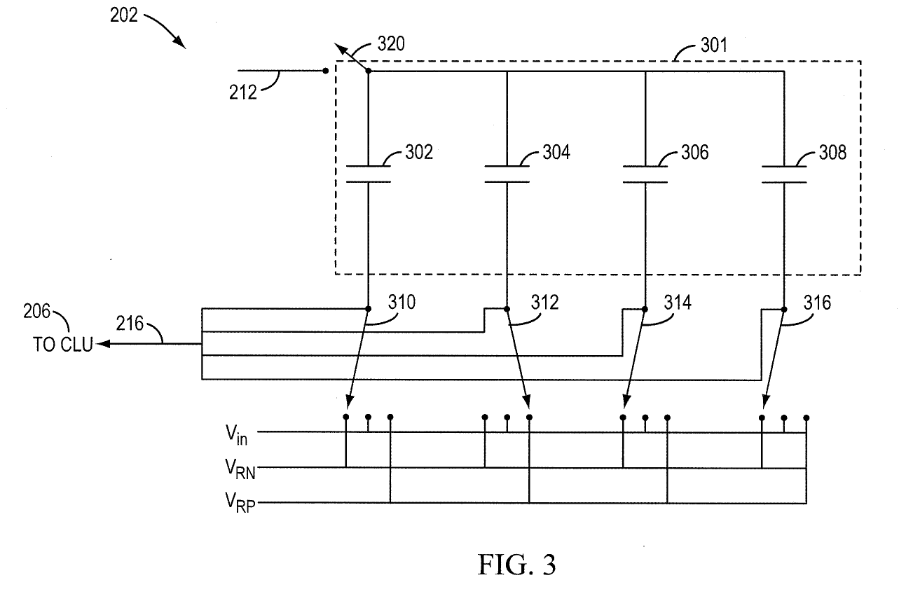

In some embodiments, DAC 202 can generate intermediate voltage signal V_{INT} by normalizing input voltage Vᵢₙ to be in a range within reference voltages V_{RP} and V_{RN}. As will be discussed later with respect to FIG. 3, DAC 202 can include an array of capacitors that can generate different output voltages by switching input signals to one or more capacitors. For a given input voltage sample Vᵢₙ, during each iteration, CLU 206 can generate intermediate digital code 216 (as discussed above) that can switch one or more capacitors to generate intermediate voltage V_{INT}. With each iteration, CLU 216 can update intermediate digital code 216 such that DAC 202 can generate a value of V_{INT} that can closely approximate Vᵢₙ. The digital code that can generate the closest approximation of input voltage sample Vᵢₙ is then related to discrete signal 107. Discrete signal 107 is then the digital output representation of input signal V.

As discussed above, the voltage level that can be generated by the capacitor array in DAC 202 (corresponding to intermediate digital code 216) can be generated by using reference voltages (V_{RN} and V_{RP}) generated by RGU 208. For example, assuming that the intermediate digital code 216 corresponds to a voltage level that has a value of Q volts, and reference voltage generated by RGU 208 equals V_{ref} (where V_{ref}=V_{RP}−V_{RN}) then the actual voltage corresponding to a digital code (such as digital code 216) equals (V_{ref}*Q)/2^{N}.

As discussed above, in order to improve accuracy and performance of ADC 106, reference voltage V_{ref} may be held at a constant predetermined level during all iterations, which may result in a more accurate generation of a digital code (such as digital code 216).

FIG. 3 illustrates an exemplary embodiment of DAC 202 consistent with the present invention. As discussed earlier and as shown in FIG. 3, DAC 202 can include a capacitor array 301 that can further include capacitors (302, 304, 306, and 308). Each of capacitors (302, 304, 306, and 308) can be coupled to receive input signals through a switch such as exemplary switch 310, 312, 314 and 316, respectively. For convenience, FIG. 3 depicts capacitor array 301 as including four capacitors (302, 304, 306, and 308). However, it should be understood that in practice, capacitor array 301 can include any number of capacitors coupled in any configuration (serial and/or parallel). Therefore, the present disclosure is not limited in the number of capacitors that can be included in a capacitor array consistent with the present invention.

As is shown in FIG. 3, each switch (such as exemplary switches 310, 312, 314 and 316) can be coupled to receive intermediate digital code 216 from CLU 206. Intermediate digital code 216 can set each switch such as switches 310, 312, 314, and 316 to couple input voltage Vᵢₙ or reference voltages V_{RP} and V_{RN} respectively, to each of capacitors 302, 304, 306, and 308. Furthermore, as shown in FIG. 3, the other end of capacitor array 301 (top end) can include a switch 320 that can couple capacitor array 301 to comparator 204 via terminal 210. In some embodiments, switch 320 can also be controlled by CLU 206. In some embodiments, in order to attain a wider range of output voltage, capacitor array 301 can include capacitors (such as capacitors 302, 304, 306 and 308) whose capacitances can be binary weighted i.e. capacitances of capacitors 302, 304, 306, and 308 can be in a ratio with one another. For example, capacitors 302, 304, 306 and 308 can include capacitances of C, 2C, 4C and 8C, respectively, where C is the capacitance of capacitor 302.

As discussed above, CLU 206 can toggle switches 310, 312, 314, and 316 of capacitor array 301 (via intermediate digital code 216) to generate an appropriate intermediate voltage V_{INT} across terminal 212. Initially, capacitors 302, 304, 306, and 308 can be charged by coupling each capacitor to a reference voltage such as reference voltages V_{RN} and V_{RP} via their respective switch. In some embodiments, one or more capacitors in capacitor array 301 can be charged by coupling with input voltage Vᵢₙ (via their respective switch). A voltage corresponding to a total charge due to one or more capacitors in capacitor array 301 can be provided to terminal 212 by closing switch 320. CLU 206 can therefore select one or more (charged) capacitors from capacitor array 301 to attain a given voltage across terminal 212 of comparator 204. Therefore, for each iteration of an input voltage sample, capacitors (302, 304, 306, and 308) of capacitor array 301 can be charged (and/or discharged) to one or more voltage levels, and CLU 206 (via digital code 216) can select one or more different combinations of capacitors from capacitor array 301.

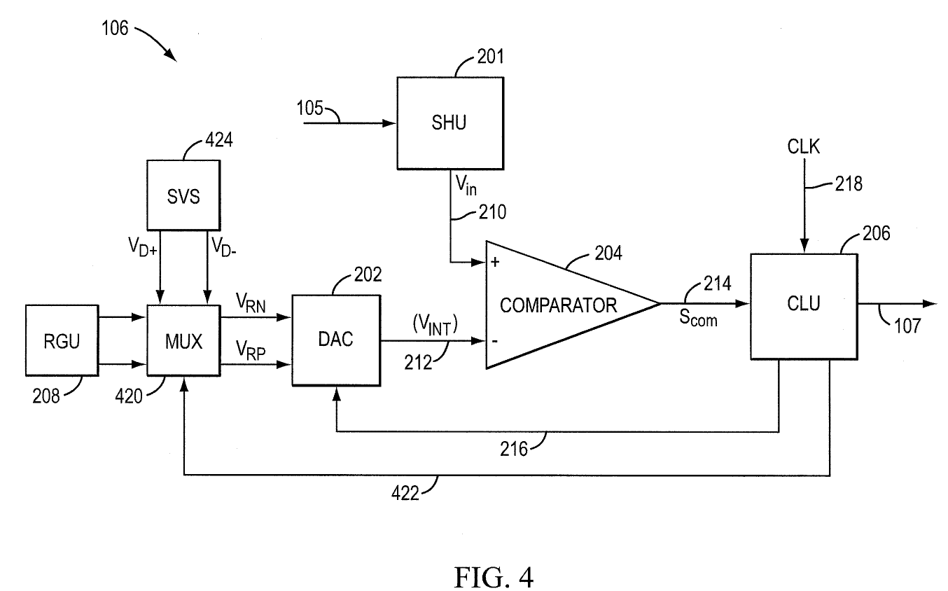

As discussed earlier, in order to improve accuracy and performance of ADC 106, reference voltages such as exemplary reference voltages V_{RP} and V_{RN} may be at a constant predetermined voltage. However, due to the repeated charging and/or discharging of capacitors in capacitor array 301, various conditions such as capacitor parasitics, current surges, etc. can exist that can affect the accuracy of reference voltages V_{RN} and V_{RP} generated by RGU 208. FIG. 4 is a block diagram illustrating an embodiment of ADC 106 that can improve reference voltage accuracy consistent with some embodiments of the present invention. As shown in FIG. 4, ADC 106 can further include a multiplexer unit (MUX) 420 that can be coupled to receive reference voltages V_{RN} and V_{RP} from RGU 208 and a control signal 422 from CLU 216. MUX 420 can be further coupled to a secondary voltage source (SVS) 424 that can generate a voltage of V_{d+} and V_{d-}. In some embodiments, SVS 424 can be unrelated to RGU 208 and can be one of the voltage sources from a multi-source chip.

To avoid the unsettling of reference voltages V_{RN} and V_{RP} due to the charging and/or discharging of one or more capacitors in capacitor array 301, in some embodiments CLU 206 can initially couple DAC 202 with SVS 424 by activating MUX 420 via control signal 422. After a given time duration or voltage level, CLU 206 can deactivate MUX 420 via control signal 422, to couple DAC 202 with reference voltages V_{RN} and V_{RP} from RGU 208. Because a final voltage output across capacitor array 301 (not shown in FIG. 4) of DAC 202 depends only on a final voltage source coupled to it (and not any intermediate voltage sources such as SVS 424), the output (V_{INT}) is not affected by SVS 424. Therefore, by first coupling DAC 202 (and in turn capacitor array 301) to a unrelated power source (such as SVS 424), effects due to charging and/or discharging of capacitors can be experienced by unrelated SVS 424 instead of RGU 208, thus a steady and constant reference voltage level can be maintained by RGU 208.

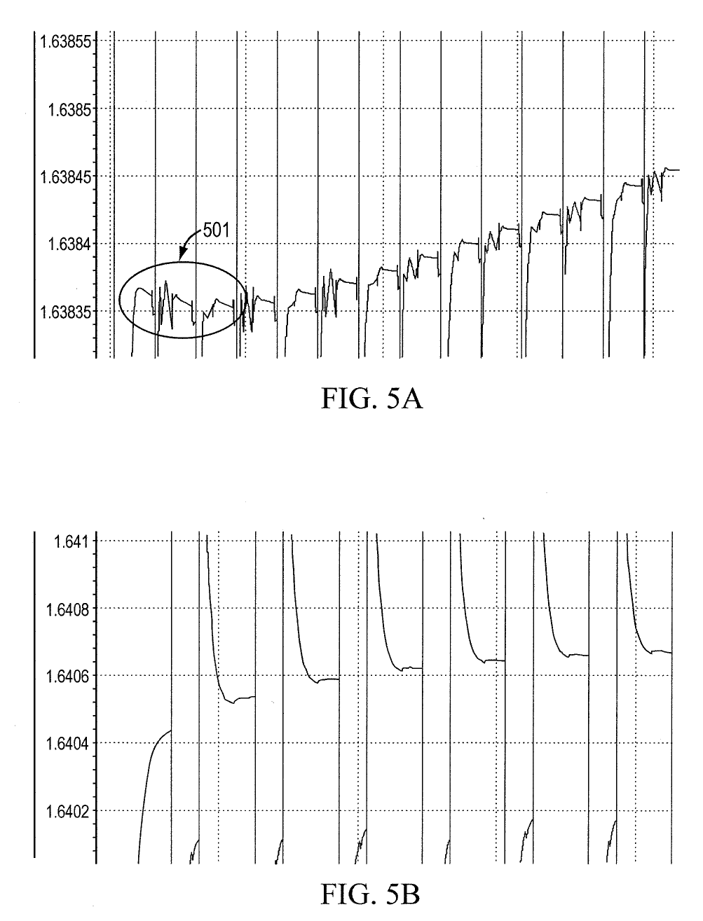

FIGS. 5a and 5b are graphs illustrating the output of ADC 106 discussed in FIGS. 2 and 4, respectively. The data for these plots were obtained by simulating operation of system 100. As is shown in FIG. 5a, an error 501 can exist due to various effects as discussed with respect to FIG. 4. As can be seen in FIG. 5b, under the same simulation conditions, error 501 can be eliminated.

It should be understood that embodiments disclosed herein can be used in an capacitor related circuit and are not limited in use to ADC's or DAC's.

Other embodiments will be apparent to those skilled in the art from consideration of the specification and practice disclosed herein. It is intended that the specification and examples be considered as exemplary only, with a true scope and spirit of the invention being indicated by the following claims.

What is claimed is:

1. An analog to digital converter (ADC) for converting an analog input voltage to a discrete signal, comprising:
a reference generator unit (RGU) for generating at least one reference voltage;
a secondary voltage source (SVS) for generating at least one secondary voltage, the at least one secondary voltage being different from the at least one reference voltage;
a multiplexer coupled to receive the at least one secondary voltage and the at least one reference voltage, the multiplexer configured to select between the at least one reference voltage and the at least one secondary voltage based on a control signal;
a digital to analog converter (DAC) coupled to receive the analog input voltage, at least one voltage from the multiplexer, and at least one digital code, the DAC further generating at least one intermediate voltage based on the at least one digital code;
a comparator coupled to receive the analog input voltage and the at least one intermediate voltage, the comparator further configured to generate at least one comparison signal; and
a control logic unit (CLU) coupled to receive a clock signal and the comparison signal, the CLU configured to generate the control signal and the at least one digital code, the CLU further generating the discrete signal.

2. The ADC of claim 1 wherein, the at least one reference voltage and the at least one secondary voltage are the same voltage.

3. The ADC of claim 1 wherein, the control signal received by the multiplexer is a binary signal including at least one binary bit.

4. The ADC of claim 1 wherein, the DAC further includes a plurality of capacitors coupled together, the plurality of capacitor configured to generate the at least one intermediate voltage based on the at least one digital code.

5. A method for converting an analog input voltage signal to a discrete signal, including:
generating at least one reference voltage and at least one secondary voltage;
selecting, at least one voltage between the at least one reference voltage and the at least one secondary voltage;
generating at least one intermediate voltage based on the at least one voltage and at least one digital code;
generating at least one comparison signal based on the at least one intermediate voltage and the analog input voltage; and
generating the discrete signal based on the at least one comparison signal and the at least one digital.

6. The method of claim 5 wherein, generating the at least one reference voltage and the at least one secondary voltage includes the at least one reference voltage being different from the at least one secondary voltage.

7. The method of claim 5 wherein, selecting the at least one voltage between the at least one reference voltage and the at least one secondary voltage includes selecting the at least one voltage based on a control signal.

8. The method of claim 7 wherein, selecting the at least one voltage based the a control signal include the control signal being a binary signal including at least one bit.
